(19) United States
(12) Patent Application Publication
(10) Pub. No.: US 2026/0343873 A1
(43) Pub. Date: Oct. 29, 2026

(54) INTELLIGENT DRAM CHIP, ARTIFICIAL INTELLIGENCE SYSTEM AND AN IMAGE PROCESSING SYSTEM

(71) Applicant: Etron Technology, Inc., Hsinchu (TW)

(72) Inventors: Chun Shiah, Hsinchu City (TW); Po-Ting Yeh, Hsinchu (TW); Hsin-Hung Lu, Hsinchu (TW)

(73) Assignee: Etron Technology, Inc., Hsinchu (TW)

(21) Appl. No.: 19/657,026

(22) Filed: Apr. 24, 2026

Related U.S. Application Data
(60) Provisional application No. 63/794,318, filed on Apr. 24, 2025.

(51) Int. Cl. H10B 12/00; H10B 80/00; H10W 20/20; H10W 70/60; H10W 70/652; H10W 90/00

(52) U.S. Cl. CPC H10B 12/50; H10B 80/00; H10W 20/233; H10W 70/611; H10W 70/652; H10W 90/724

(57) ABSTRACT

Another embodiment of the present invention provides an AI system. The AI system includes an LLM chip and at least one iDRAM chip connecting to the LLM chip. Each iDRAM chip of the at least one iDRAM chip includes a plurality of DRAM arrays and at least one logic circuit, wherein the plurality of DRAM arrays and the logic circuit are fabricated by a same DRAM process.

### CROSS REFERENCE TO RELATED APPLICATIONS

This application claims the benefit of U.S. Provisional Application No. 63/794,318, filed on Apr. 24, 2025. The content of the application is incorporated herein by reference.

### BACKGROUND OF THE INVENTION

### 1. Field of the Invention

The present invention relates to intelligent DRAM (iDRAM) chip, an Artificial Intelligence (AI) system and an image processing system, and particularly to an iDRAM chip, an AI system and an image processing system which makes a plurality of DRAM (dynamic random-access memory) arrays and a logic circuit fabricated by a same DRAM process, so that the iDRAM chip, the AI system and the image processing system have lower power, higher bandwidth, lower cost and better performance.

### 2. Description of the Prior Art

Please refer to FIG. 1, wherein FIG. 1(a) shows a top view of coupling relationships between four dynamic random-access memory (DRAM) chips 102 and a logic chip 104 according to the prior art, and a size of the DRAM chip 102 is (14472+80) um*(7161+80) um. As shown in FIG. 1, the four dynamic random-access memory (DRAM) chips 102 and the logic circuit chip 104 are installed on a silicon interposer 106, and the four dynamic random-access memory (DRAM) chips 102 and the logic circuit chip 104 are packaged in a ball grid array (BGA) package (not shown in FIG. 1(a)) and can be divided into four regions, wherein FIG. 1 takes region1 110 as an example. As shown in FIG. 1, the region1 110 has DWB (direct wafer bonding) 1/CTR1/PHY1/NPU (neural processing unit) 1 between the dynamic random-access memory (DRAM) chip 102 and the logic circuit chip 104, VDDQ (1.2V), VDD (1.2V), VDD (1.8V), and VDD_(CTR+PHY+NPU) 0.9V. In addition, the dynamic random-access memory (DRAM) chip 102 in the region1 110 has 16 BYTES, and a total number (578) of wire bond pad list of the region1 110 for DWB1/CTR1/PHY1 are shown as follows, wherein each wire bond length is less than 1 mm for 3200 Mbps data rate:
VDDQ: 11×8=88
VSSQ: 12×8=96
VDD (1.2V): 8×8=64
VDD (1.8V): 4+2=6
VSS: 8×8=64
VSS Return 4
VDD_(PHY+CTR)0.9V: 64+64
VSS_(PHY+CTR)0.9V: 64+64

In addition, as shown in FIG. 1(a), the silicon interposer 106 is connected to a ball grid array (BGA) substrate 108 through bonding wires 112. As shown in FIG. 1(b), there are BGA balls 114 under the BGA substrate 108, wherein FIG. 1(b) is a three-dimensional view of FIG. 1(a). In addition, as shown in FIG. 1(c), in the region1 110, there are 300 ubumps and 400 interposer traces between a region A of the DRAM chip 102 and a region B of the logic circuit chip 104, wherein X_pitch in the region A and the region B is 110 um, Y_pitch in the region A and the region B is 160 μm, and interposer trace pitch is 6~7 um average, wherein FIG. 1(c) is a local magnified view of FIG. 1(a).

Next, please refer to Table 1 (with silicon interposer) and Table 2 (without silicon interposer), wherein Table 1 and Table 2 are cost structure of an end point high performance AI mini system. As shown in Table 1 (with silicon interposer) and Table 2 (without silicon interposer), package cost accounts for a high percentage of total cost. For example, in Table 1 (with silicon interposer), package cost accounts for 60.2% (interposer die cost 27.77%+package 2.5D 32.43%) of total cost, and in Table 2 (without silicon interposer), package cost accounts for 65.53% (package FOCOS (fan-out chip on substrate 65.53%) of total cost. Table 1 (with silicon interposer) and Table 2 (without silicon interposer) are shown as follows:

TABLE 1

| DRAM die | Logic die | interposer | package | Final | |
|---|---|---|---|---|---|
| cost | cost | die cost | 2.5 D | test | sum |
| 26.06% | 13.2% | 27.77% | 32.43% | 0.54% | 100% |

TABLE 2

| DRAM die | Logic | | package | Final | |
|---|---|---|---|---|---|
| cost | die cost | | FOCOS | test | sum |
| 22.57% | 11.43% | 0% | 65.53% | 0.47% | 100% |

Therefore, according to Table 2 (without silicon interposer), no silicon interposer can significantly reduce package cost, so the present invention provides an iDRAM structure without silicon interposer to reduce package cost.

### SUMMARY OF THE INVENTION

An embodiment of the present invention provides an intelligent DRAM (iDRAM) chip. The iDRAM chip includes a plurality of DRAM (dynamic random-access memory) arrays and at least one logic circuit. The plurality of DRAM (dynamic random-access memory) arrays and the logic circuit are fabricated by a same DRAM process.

According to one aspect of the present invention, both the plurality of DRAM arrays and the at least one logic circuit are further packaged by a simple flip chip package, and the simple flip chip package connects to a ball grid array (BGA) substrate directly through ubumps.

According to one aspect of the present invention, the iDRAM chip further includes internal traces, and the plurality of DRAM arrays are connected to the at least one logic circuit through the internal traces.

According to one aspect of the present invention, the iDRAM chip is connected to a large language model (LLM) chip, and the at least one logic circuit includes a RISC-V core.

According to one aspect of the present invention, the iDRAM chip further includes a USB or PCIE (Peripheral Component Interconnect Express) circuit and a SRAM (static random-access memory), wherein the SRAM is fabricated by the same DRAM process.

According to one aspect of the present invention, the iDRAM chip is connected to an LLM chip, the at least one logic circuit includes an AI (Artificial Intelligence) accelerator and a RISC-V core.

According to one aspect of the present invention, the iDRAM chip further includes a USB or PCIE circuit and a SRAM, wherein the SRAM is fabricated by the same DRAM process.

According to one aspect of the present invention, the iDRAM chip is connected to an image processing chip, the at least one logic circuit includes MIPI (Mobile Industry Processor Interface) RX, ISP (Image Signal Processor) processor, splitter, dewarp processor, and JPEG & stream merge processor.

According to one aspect of the present invention, the iDRAM chip further includes a USB or PCIE circuit and a SRAM, wherein the SRAM is fabricated by the same DRAM process.

Another embodiment of the present invention provides an AI system. The AI system includes an LLM chip and at least one iDRAM chip connecting to the LLM chip. Each iDRAM chip of the at least one iDRAM chip includes a plurality of DRAM arrays and at least one logic circuit, wherein the plurality of DRAM arrays and the logic circuit are fabricated by a same DRAM process.

According to one aspect of the present invention, both the plurality of DRAM arrays and the at least one logic circuit are further packaged by a simple flip chip package, and the simple flip chip package connects to a ball grid array (BGA) substrate directly through ubumps.

According to one aspect of the present invention, the iDRAM chip further includes internal traces, and the plurality of DRAM arrays are connected to the at least one logic circuit through the internal traces.

According to one aspect of the present invention, the at least one logic circuit includes a RISC-V core.

According to one aspect of the present invention, the iDRAM chip further includes a USB or PCIE circuit and a SRAM, and the SRAM is fabricated by the same DRAM process.

According to one aspect of the present invention, the LLM chip at least includes a RISC-V core.

According to one aspect of the present invention, the at least one logic circuit includes an AI (Artificial Intelligence) accelerator and a RISC-V core.

According to one aspect of the present invention, the iDRAM chip further includes a USB or PCIE circuit and a SRAM, wherein the SRAM is fabricated by the same DRAM process.

According to one aspect of the present invention, the LLM chip at least includes an AI accelerator and a RISC-V core.

Another embodiment of the present invention provides an image processing system. The image processing system includes an image processing chip and at least one iDRAM chip connecting the image processing chip. Each iDRAM chip of the at least one iDRAM chip includes a plurality of DRAM arrays and at least one logic circuit, wherein the plurality of DRAM arrays and the logic circuit are fabricated by a same DRAM process.

According to one aspect of the present invention, the at least one logic circuit includes MIPI RX, ISP processor, splitter, dewarp processor, and JPEG & stream merge processor.

According to one aspect of the present invention, the iDRAM chip further includes a USB or PCIE circuit and a SRAM, and the SRAM is fabricated by the same DRAM process.

According to one aspect of the present invention, the LLM chip at least includes MIPI RX, ISP processor, splitter, dewarp processor, JPEG & stream merge processor and a RISC-V core.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows coupling relationships between four dynamic random-access memory (DRAM) chips and a logic chip according to the prior art.

FIG. 2 shows an intelligent DRAM (iDRAM) chip according to one embodiment of the present invention.

FIG. 3 shows data path flow between LLM (large language model) chip, DRAM and a host according to the prior art.

FIG. 4 shows data path flow between the LLM chip, the DRAM, an iDRAM and the host according to one embodiment of the present invention.

FIG. 5 shows multiple iDRAM connected to the LLM chip through PCIE bus.

FIG. 6 shows data path flow between LLM chip, the DRAM and the host according to the prior art.

FIG. 7 shows data path flow between the LLM chip, the DRAM, an iDRAM and the host according to one embodiment of the present invention.

FIG. 8 shows multiple iDRAM connected to the LLM chip through PCIE bus.

FIG. 9 shows data path flow between image processing chip and DRAM chip according to the prior art.

FIG. 10A shows data path flow within an iDRAM which is connected to an image processing chip according to one embodiment of the present invention.

FIG. 10B shows image signals inputted into the multiple iDRAMs in parallel manner.

### DETAILED DESCRIPTION

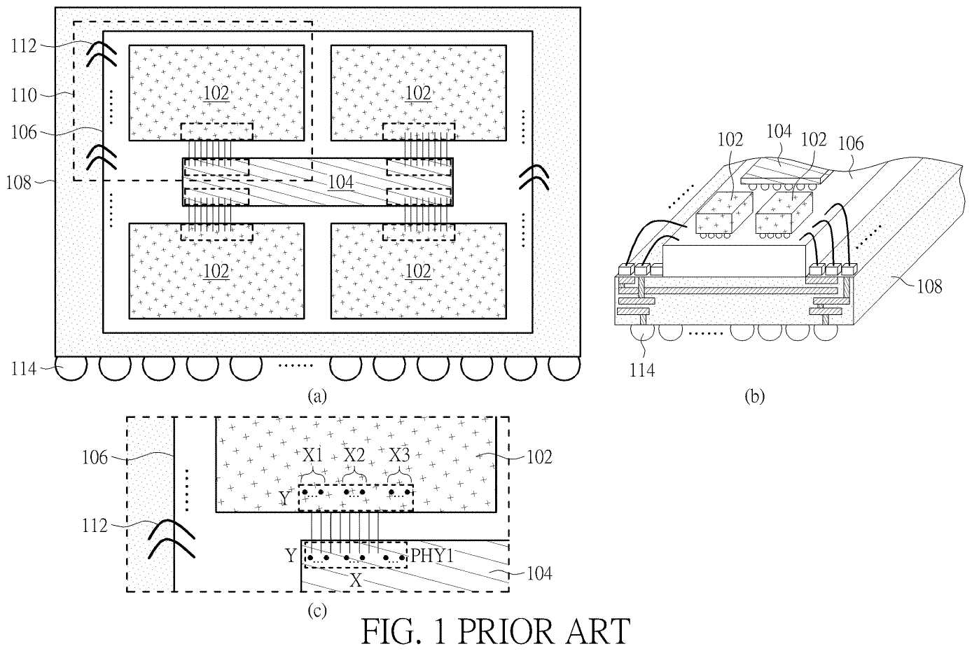

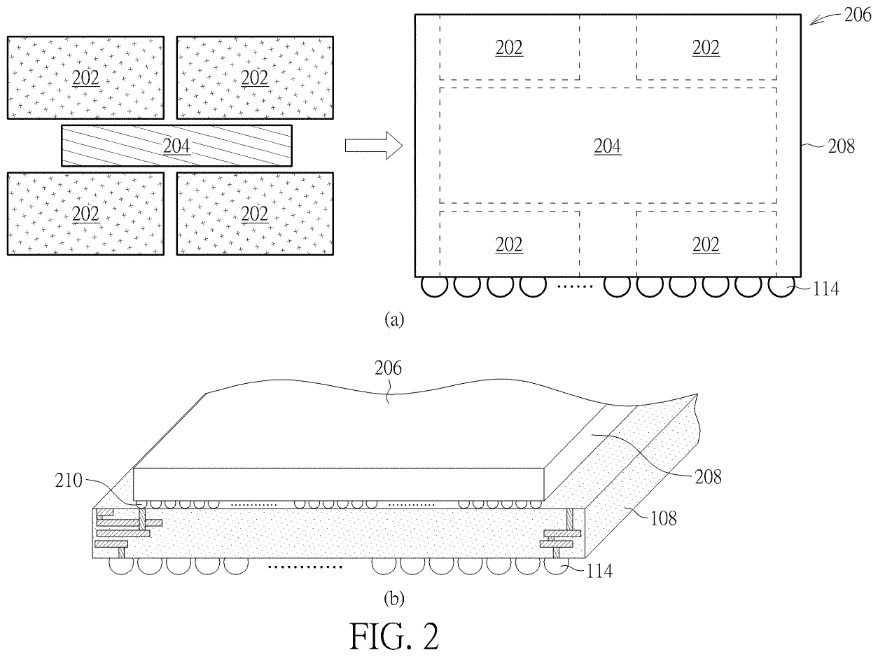

Please refer to FIG. 2. FIG. 2 shows an intelligent DRAM (iDRAM) chip according to one embodiment of the present invention. As shown in right diagram FIG. 2(a), four DRAM chips 202 and a logic chip 204 are fabricated by the same DRAM process and integrated into 1 or 4 iDRAM 206. Therefore, because the four DRAM chips 202 and the logic chip 204 are fabricated by the same DRAM process, compared to FIG. 1, the iDRAM 206 has no silicon interposer, no wire bond to the BGA substrate 108 and no voltage conversion between the DRAM chips 202 and the logic chip 204, resulting in the iDRAM 206 having lower cost, lower power and better performance. In addition, because the DRAM chips 202 and the logic chip 204 are fabricated by the same DRAM process, the interposer traces between the DRAM chip 102 and the logic circuit chip 104 shown in FIG. 1(a) will become internal traces between the DRAM chips 202 and the logic chip 204, resulting in the iDRAM 206 saving 10× power and increasing 10× data transmission speed. In addition, because the DRAM chips 202 and the logic chip 204 are fabricated by the same DRAM process, the iDRAM 206 can be packaged by simple flip chip (uBump) package 208. Therefore, because the DRAM chips 202 and the logic chip 204 of the iDRAM 206 can be packaged by the same flip chip (uBump) package 208, the flip chip (uBump) package 208 connects to the BGA substrate 108 only through ubumps 210, not needing through interposer to connect to the BGA substrate 108 anymore, wherein the flip chip (uBump) package 208 can save 50% of total cost of the iDRAM 206. In addition, the iDRAM 206 is not limited to the number of the DRAM chips 202.

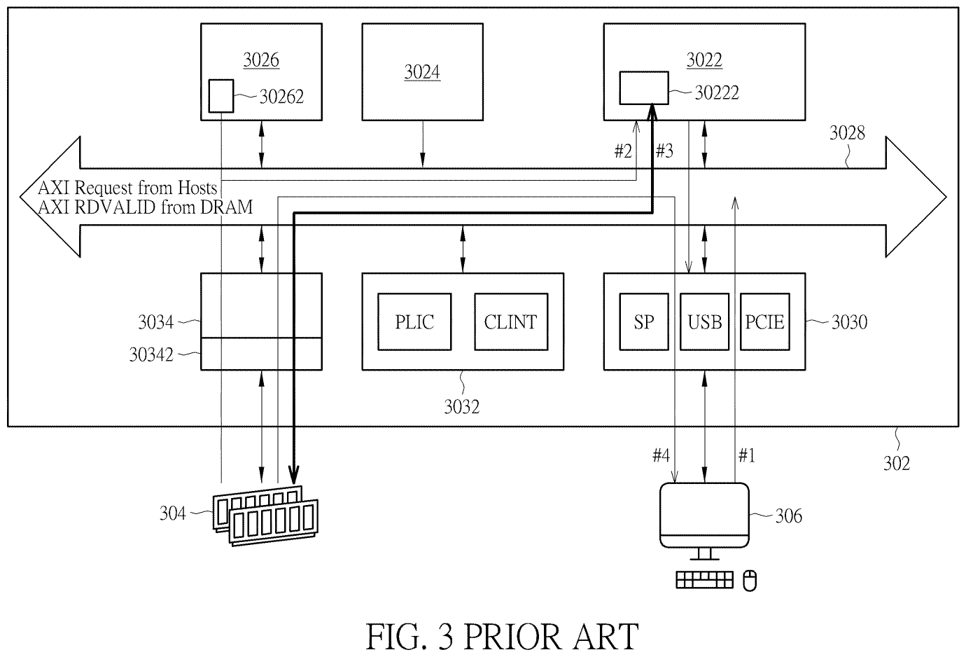

Next, please refer to FIG. 3. FIG. 3 shows data path flow between LLM (large language model) chip 302, DRAM 304 and a host 306 according to the prior art, wherein FIG. 3 takes an LLM (large language model) system applied for AI model application as an example. As shown in FIG. 3, data path #1 represents that initially, the host 306 issues software instruction to a system RAM 3026 or DRAM 304 of the LLM chip 302, wherein the software instruction is transmitted to the system RAM 3026 or the DRAM 304 through an AXI (Advanced eXtensible Interface) bus 3028 of the LLM chip 302. Then, data path #2 represents that when an instruction set 30262 issues GEMV (General Matrix-Vector Multiplication) operation to a RISC-V core 3022 of the LLM chip 302. Then, data path #3 represents that the RISC-V core 3022 will start to read large amount of Q/K/V weight values from the DRAM 304 and do the calculations in ALU (Arithmetic logic unit) units 30222 inside the RISC-V core 3022, wherein as shown in FIG. 3, because data path #3 has long external traces and crosses different packages between the DRAM 304 and PHY 30342 of the DRAM controller 3034, data path #3 has C_load1 which consumes high power and has low speed since C_load1 is very large (wherein C_load1 represents heavy (long) loading between the RISC-V core 3022 and the DRAM 304 causing delay and power). Finally, data path #4 represents that the RISC-V core 3022 enables peripheral DMA (Direct Memory Access) to read data from the DRAM 304 and a display of the host 306. In addition, in another embodiment of the present invention, the RISC-V core 3022 can be replaced with x86 core. In addition, the LLM chip 302 further includes an interrupt controller 3032, a peripheral circuit 3030 and a boot ROM (Read-Only Memory) 3024, the interrupt controller 3032 includes PLIC (Platform-Level Interrupt Controller) unit and CLINT (Core Local Interrupter) unit, and the peripheral circuit 3030 includes SPI (Serial Peripheral Interface) unit, USB unit and PCIE (Peripheral Component Interconnect Express) unit.

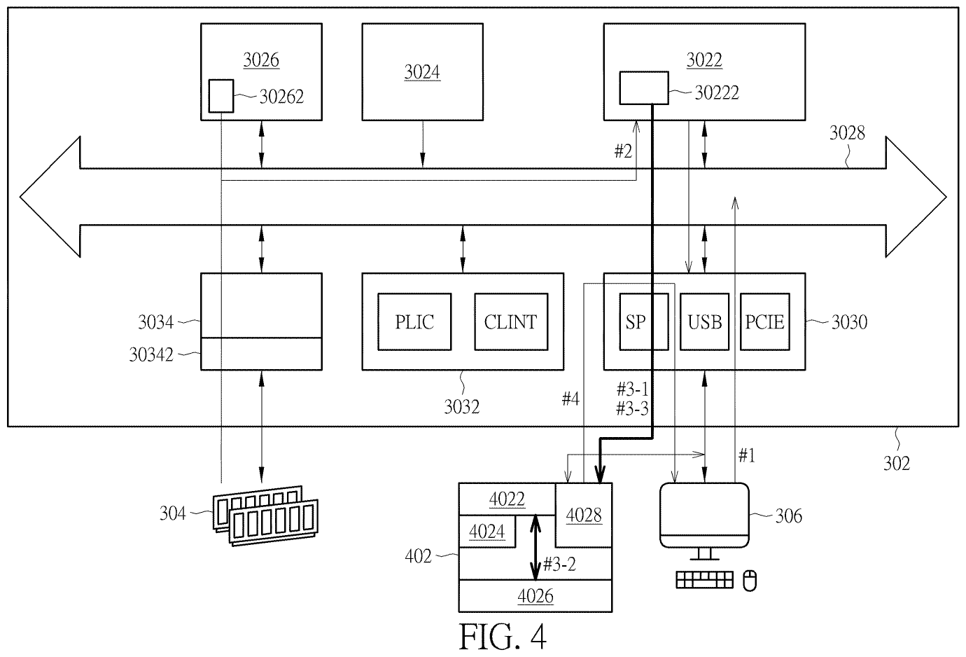

Next, please refer to FIG. 4. FIG. 4 shows data path flow between the LLM chip 302, the DRAM 304, an iDRAM 402 and the host 306 according to one embodiment of the present invention, wherein the iDRAM 402 includes a RISC-V core 4022, SRAM array 4024, DRAM cell array 4026 and USB (or PCIE) circuit 4028. As shown in FIG. 4, differences between FIG. 3 and FIG. 4 are that data path #3-1 represents that the RISC-V core 3022 will enable RISC-V core 4022 of the iDRAM 402, data path #3-2 represents that start computing AI operators inside the iDRAM 402, data path #3-3 represents that when the iDRAM 402 calculators is done, the RISC-V core 3022 polls DRAM interrupt to the RISC-V core 4022, and data path #4 represents that the RISC-V core 4022 of the iDRAM 402 enables peripheral DMA (Direct Memory Access) to read data from the DRAM 304 and the display of the host 306. It is noted that because data path #3-2 exists between the RISC-V core 4022 and the DRAM cell array 4026 (that is, data path #3-2 exists inside the iDRAM 402), data path #3-2 can be reduce large amount of delay and power. That is, data path #3-2 has C_load2 which represents very small loading inside the iDRAM 402 (because only internal lines between the RISC-V core 4022 and the DRAM cell array 4026), lower Power and higher computing performance. In addition, as shown in FIG. 4, the host 306 still can use the external Boot ROM 3024 for initialization, the SRAM array 4024 design can be made by DRAM's bit line sense amplification macros which keeps the same DRAM technology, data path #3-2 includes internal traces between the RISC-V core 4022 and the DRAM cell array 4026 which improve speed and power, and same package between the iDRAM 402 and the PHY 30342 of the LLM chip 302 can reduce cost.

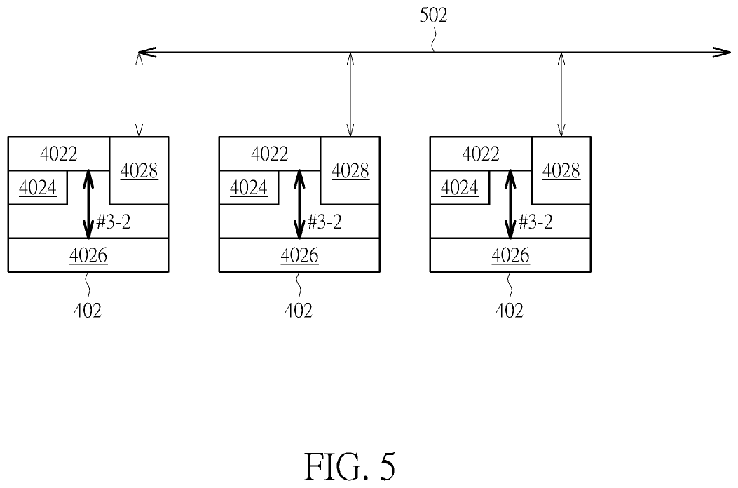

In addition, the present invention is not limited to the LLM chip 302 connecting to one iDRAM 402, that is, as shown in FIG. 5, the LLM chip 302 can connect to more than one iDRAM 402 through PCIE bus 502 or others.

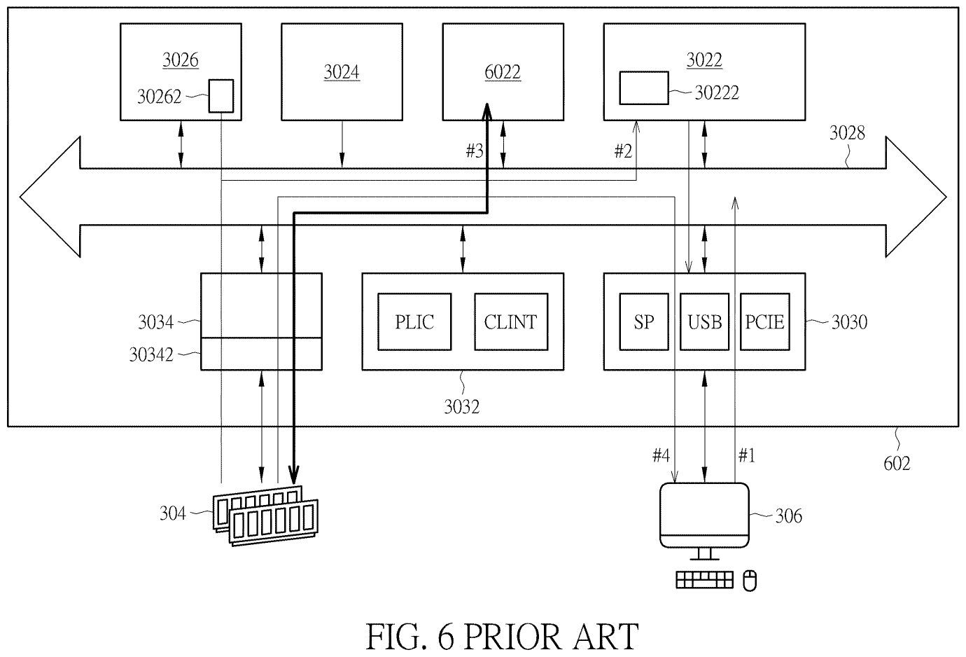

Next, please refer to FIG. 6. FIG. 6 shows data path flow between LLM chip 602, the DRAM 304 and the host 306 according to the prior art, wherein compared to the LLM chip 302, the LLM chip 602 further includes AI accelerator 6022. In addition, data path #1, data path #2 and data path #4 shown in FIG. 6 are the same as data path #1, data path #2 and data path #4 shown in FIG. 3, so further description thereof is omitted for simplicity. As shown in FIG. 6, data path #3 represents that the RISC-V core 3022 enables the AI accelerator 6022 to do the calculations and will start to read large amount of Q/K/V weight values from the DRAM 304 and to do GEMV operators; and finally the results will be written back to the DRAM 304. Therefore, data path #3 still has long external traces and crosses different packages between the DRAM 304 and PHY 30342 of the DRAM controller 3034, so data path #3 has C_load1 which consumes high power and has low speed since C_load1 is very large (wherein C_load1 represents heavy (long) loading between the AI accelerator 6022 and the DRAM 304 causing delay and power).

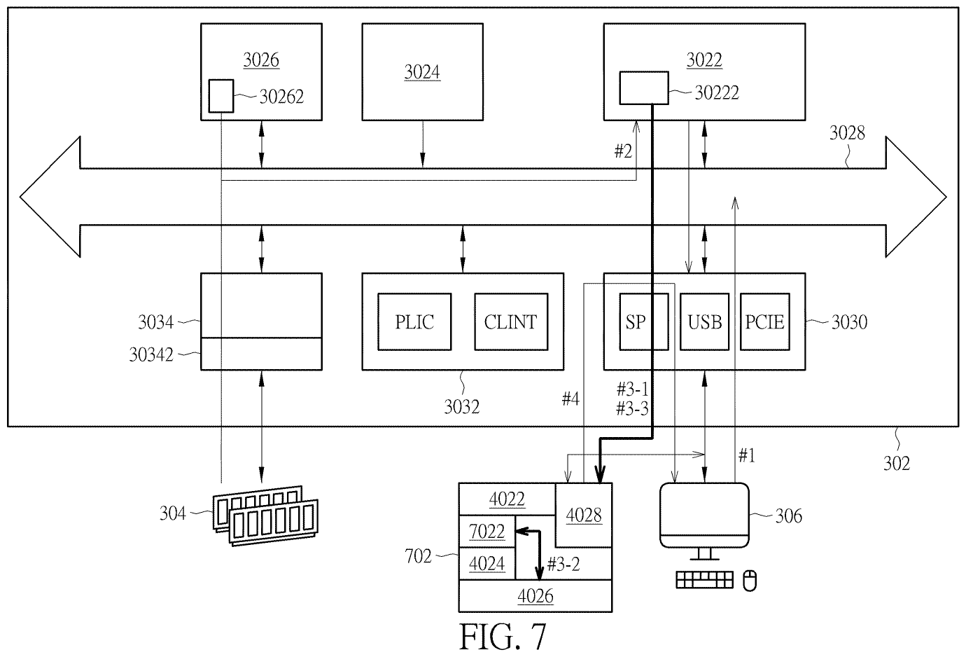

Next, please refer to FIG. 7. FIG. 7 shows data path flow between the LLM chip 302, the DRAM 304, an iDRAM 702 and the host 306 according to one embodiment of the present invention, wherein compared to the iDRAM 402, the iDRAM 702 further includes an AI accelerator 7022. As shown in FIG. 7, differences between FIG. 6 and FIG. 7 are that data path #3-1 represents that the RISC-V core 3022 will enable the AI accelerator 7022 of the iDRAM 702, data path #3-2 represents that the AI accelerator 7022 starts computing AI operators inside the iDRAM 702, reads large amount of Q/K/V weight values from the DRAM cell array 4026 and to do GEMV operators, wherein data path #3-2 can reduce large amount of delay and power, data path #3-3 represents that when the iDRAM 702 calculators is done, the RISC-V core 3022 polls DRAM interrupt to the RISC-V core 4022, and data path #4 represents that the RISC-V core 4022 of the iDRAM 702 enables peripheral DMA (Direct Memory Access) to read data from the DRAM 304 and the display of the host 306. It is noted that because data path #3-2 exists between the AI accelerator 7022 and the DRAM cell array 4026 (that is, data path #3-2 exists inside the iDRAM 702), data path #3-2 can be reduce large amount of delay and power. That is, data path #3-2 has C_load2 which represents very small loading inside the iDRAM 702 (because only internal lines between the AI accelerator 7022 and the DRAM cell array 4026), lower Power and higher computing performance. In addition, as shown in FIG. 7, the host 306 still can use the external Boot ROM 3024 for initialization, the SRAM array 4024 design can be made by DRAM's bit line sense amplification macros which keeps the same DRAM technology, data path #3-2 includes internal traces between the AI accelerator 7022 and the DRAM cell array 4026 which improve speed and power, and same package between the iDRAM 702 and the PHY 30342 of the LLM chip 302 can reduce cost.

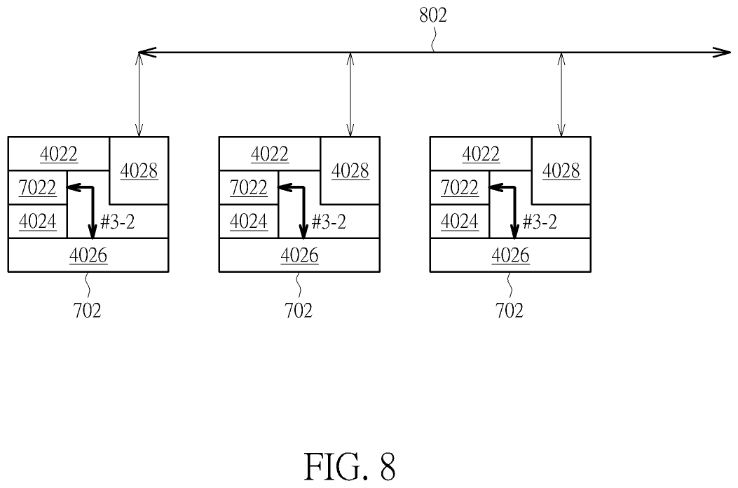

In addition, the present invention is also not limited to the LLM chip 302 connecting to one iDRAM 702, that is, as shown in FIG. 8, the LLM chip 302 can connect to more than one iDRAM 702 through PCIE bus 802 or others.

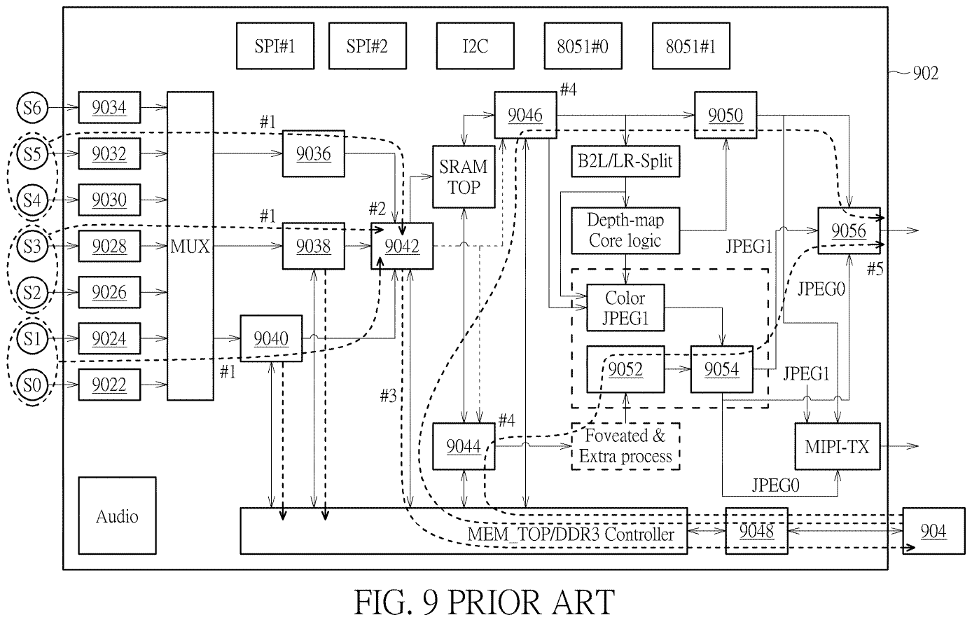

Next, please refer to FIG. 9. FIG. 9 shows data path flow between image processing chip 902 and DRAM chip (e.g. DDR3 DRAM chip) 904 according to the prior art. As shown in FIG. 9, data path #1 represents that MIPI (Mobile Industry Processor Interface) RXs 9022~9034 receive data to ISP (Image Signal Processor) processors 9036~9040. Then, data path #2 represents that the data are transferred to splitter 9042 or store to the cell array of the DRAM chip 904 after ISP processing by the ISP processors 9036~9040. Then, data path #3 represents that after the data are processed by the splitter 9042, the data are written into the cell array of the DRAM chip 904. Then, data path #4 represents that read amount of data from the cell array of the DRAM chip 904 and execute dewarp operation within dewarp processors 9044, 9046, wherein as shown in FIG. 9, because data path #4 has long external traces and crosses different packages between the DRAM chip 904 and DDR3 PHY 9048 of the image processing chip 902, data path #4 has C_load1 which consumes high power and has low speed since C_load1 is very large (wherein C_load1 represents heavy (long) loading between the dewarp processors 9044, 9046 and the DRAM chip 904 causing delay and power). Finally, data path #5 represents that execute JPEG function within JPEG processors 9050, 9052 and merge function within stream merge processor 9054 and display from USB (or PCIE) circuit 9056. In addition, as shown in FIG. 9, remaining components (e.g. SPI(Serial Peripheral Interface) #1, SPI #2, I2C, 8051 #0, 8051 #1, MUX, Audio, SRAM TOP, B2L/LR-Split, Depth-map Core logic, Color JPEG1, Foveated & Extra process, MEM_TOP/DDR3 Controller and MIPI-TX) of the image processing chip 902 are well-known to one of ordinary skilled in the art and not key technical features of the present invention, so further description thereof is omitted for simplicity.

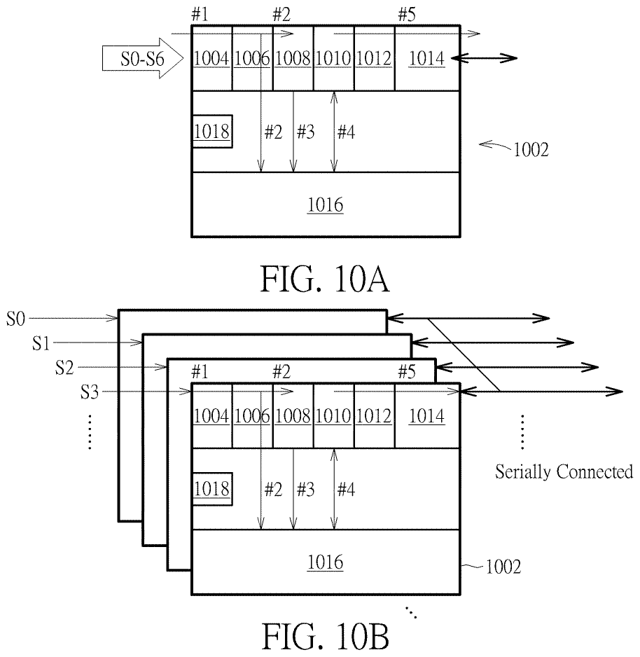

Next, please refer to FIG. 10A, wherein FIG. 10A shows data path flow within an iDRAM 1002 which is connected to an image processing chip 902 according to one embodiment of the present invention, and MIPI RX 1004, ISP processor 1006, splitter 1008, dewarp processor 1010, JPEG & stream merge processor 1012, USB (or PCIE) circuit 1014, cell array 1016 and SRAM 1018 are fabricated by the same DRAM process and integrated into the iDRAM 1002. In addition, functions of data path #1, data path #2, data path #3, data path #4 and data path #5 can be referred to descriptions corresponding to FIG. 9, so further description thereof is omitted for simplicity. In addition, as shown in FIG. 10A, image signals S0~S6 are inputted into the MIPI RX 1004 in serial manner. As shown in FIG. 10A, because the dewarp processor 1010 and the cell array 1016 are integrated into the iDRAM 1002, data path #4 is shorter, resulting in data path #4 having C_load2 which represents very small loading inside the iDRAM 1002 (because only internal lines between the dewarp processor 1010 and the cell array 1016), lower Power and higher computing performance. In addition, similarly, as shown in FIG. 10A, the iDRAM 1002 still can use the external Boot ROM for initialization, the SPAM 1018 design can be made by DRAM's bit line sense amplification macros which keeps the same DRAM technology, data path #1, data path #2, data path #3, data path #4 and data path #5 include internal traces which improve speed and power, and same package utilized in the iDRAM 1002 can reduce cost.

In addition, in another embodiment of the present invention, as shown in FIG. 10B, outputs of multiple iDRAMs 1002 are serially connected to together and each of the multiple iDRAMs 1002 receives a corresponding image signal. That is, as shown in FIG. 10B, image signals S0, S1, S2, . . . can be inputted into the multiple iDRAMs 1002 in parallel manner.

To sum up, the present invention provides the iDRAM, and the iDRAM is an intelligent DRAM chip with active circuits or IP(s) designed inside DRAM using peripheral devices thereof like thin or thick oxide MOSFET (Metal-Oxide-Semiconductor Field-Effect Transistor), AA (active region) or Poly resistors . . . , wherein these active circuits or IP(s) were designed using Foundry Technology conventionally, so compared to the prior art, the iDRAM offers the following advantages. These active circuits or IPs are not to re-design any of the cell structure or cell arrays (not CIM(Computer-Integrated Manufacturing)). These active circuits or IPs are designed using DRAM technology. These active circuits or IPs generally requires heavily on large data movement (bandwidth) between DRAM cells and corresponding circuits or IP(s), so the iDRAM has higher bandwidth when using the iDRAM. These Active circuits or IP(s) also consumes heavily on Interface Power between DRAM cells and corresponding circuits or IP(s), so the iDRAM has lower power when using iDRAM. Because of no more heterogeneous integration with heavy wire bonds/flip chip or COWAS (Chip-on-Wafer-on-Substrate) connections between DRAM and SOC (System on a Chip), only iDRAM package (Single Die) is needed. In addition, the iDRAM uses common interface protocols like USB or PCIE or SPI or I2C . . . to connect to other devices, for example, request examples from USB (TX packet) or from PCIE (TX packet) or from SPI (MOSI (Master Out Slave In) TX command) or from I2C (start command) and response examples from USB (RX packet) or from PCIE (RX packet) or from SPI (MISO (Master In Slave Out) RX) or from I2C (ACK). In addition, no more heterogeneous PHY is inside the iDRAM (no transmission line effect, no package effect, no training required). The iDRAM still need DRAM Controller to optimize column performance using look ahead circuit design. In addition, SRAM array Design inside iDRAM can be made by DRAM's Bit Line Sense Amplification macros which keeps the same DRAM technology

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. An intelligent DRAM (iDRAM) chip comprising:
a plurality of DRAM (dynamic random-access memory) arrays; and
at least one logic circuit, wherein the plurality of DRAM (dynamic random-access memory) arrays and the logic circuit are fabricated by a same DRAM process.

2. The iDRAM chip of claim 1, wherein both the plurality of DRAM arrays and the at least one logic circuit are further packaged by a simple flip chip package, and the simple flip chip package connects to a ball grid array (BGA) substrate directly through ubumps.

3. The iDRAM chip of claim 1, further comprising internal traces, and the plurality of DRAM arrays are connected to the at least one logic circuit through the internal traces.

4. The iDRAM chip of claim 1, wherein the iDRAM chip is connected to a large language model (LLM) chip, and the at least one logic circuit comprises a RISC-V core.

5. The iDRAM chip of claim 4, further comprising a USB or PCIE (Peripheral Component Interconnect Express) circuit and a SRAM (static random-access memory), wherein the SRAM is fabricated by the same DRAM process.

6. The iDRAM chip of claim 1, wherein the iDRAM chip is connected to an LLM chip, the at least one logic circuit comprises an AI (Artificial Intelligence) accelerator and a RISC-V core.

7. The iDRAM chip of claim 6, further comprising a USB or PCIE circuit and a SRAM, wherein the SRAM is fabricated by the same DRAM process.

8. The iDRAM chip of claim 1, wherein the iDRAM chip is connected to an image processing chip, the at least one logic circuit comprises MIPI (Mobile Industry Processor Interface) RX, ISP (Image Signal Processor) processor, splitter, dewarp processor, and JPEG & stream merge processor.

9. The iDRAM chip of claim 8, further comprising a USB or PCIE circuit and a SRAM, wherein the SRAM is fabricated by the same DRAM process.

10. An AI system comprising:
an LLM chip; and
at least one iDRAM chip connecting to the LLM chip, each iDRAM chip of the at least one iDRAM chip comprising:
a plurality of DRAM arrays; and
at least one logic circuit, wherein the plurality of DRAM arrays and the logic circuit are fabricated by a same DRAM process.

11. The AI system of claim 10, wherein both the plurality of DRAM arrays and the at least one logic circuit are further packaged by a simple flip chip package, and the simple flip chip package connects to a ball grid array (BGA) substrate directly through ubumps.

12. The AI system of claim 10, wherein the iDRAM chip further comprises internal traces, and the plurality of DRAM arrays are connected to the at least one logic circuit through the internal traces.

13. The AI system of claim 10, wherein the at least one logic circuit comprises a RISC-V core.

14. The AI system of claim 13, wherein the iDRAM chip further comprises a USB or PCIE circuit and a SRAM, and the SRAM is fabricated by the same DRAM process.

15. The AI system of claim 13, wherein the LLM chip at least comprises a RISC-V core.

16. The AI system of claim 10, wherein the at least one logic circuit comprises an AI (Artificial Intelligence) accelerator and a RISC-V core.

17. The AI system of claim 16, wherein the iDRAM chip further comprises a USB or PCIE circuit and a SRAM, wherein the SRAM is fabricated by the same DRAM process.

18. The AI system of claim 16, wherein the LLM chip at least comprises an AI accelerator and a RISC-V core.

19. An image processing system comprising:
an image processing chip; and
at least one iDRAM chip connecting the image processing chip, each iDRAM chip of the at least one iDRAM chip comprising:
a plurality of DRAM arrays; and
at least one logic circuit, wherein the plurality of DRAM arrays and the logic circuit are fabricated by a same DRAM process.

20. The image processing system of claim 19, wherein the at least one logic circuit comprises MIPI RX, ISP processor, splitter, dewarp processor, and JPEG & stream merge processor.

21. The image processing system of claim 19, wherein the iDRAM chip further comprises a USB or PCIE circuit and a SRAM, and the SRAM is fabricated by the same DRAM process.

22. The AI system of claim 19, wherein the LLM chip at least comprises MIPI RX, ISP processor, splitter, dewarp processor, JPEG & stream merge processor and a RISC-V core.
